(19) United States
(12) Patent Application Publication
(10) Pub. No.: US 2012/0007049 A1
(43) Pub. Date: Jan. 12, 2012

(54) NITRIDE-BASED SEMICONDUCTOR DEVICE AND METHOD FOR MANUFACTURING THE SAME

(75) Inventors: Woo Chul JEON, Gyeonggi-do (KR); Ki Yeol Park, Gyeonggi-do (KR); Jung Hee Lee, Daegu (KR); Young Hwan Park, Seoul (KR)

(73) Assignee: SAMSUNG ELECTRO-MECHANICS CO., LTD.

(21) Appl. No.: 12/917,812

(22) Filed: Nov. 2, 2010

(30) Foreign Application Priority Data
Jul. 7, 2010 (KR) 10-2010-0065423

(51) Int. Cl. H01L 29/778; H01L 21/329; H01L 21/335; H01L 29/15

(52) U.S. Cl. 257/20; 257/195; 438/369; 438/172; 257/E29.072; 257/E29.246; 257/E21.361; 257/E21.403

(57) ABSTRACT

The present invention provides a nitride-based semiconductor device. The nitride-based semiconductor device includes: a base substrate having a diode structure; an epi-growth film disposed on the base substrate; and an electrode part disposed on the epi-growth film, wherein the diode structure includes: first-type semiconductor layers; and a second-type semiconductor layer which is disposed within the first-type semiconductor layers and has both sides covered by the first-type semiconductor layers.

### CROSS-REFERENCE TO RELATED APPLICATIONS

This application claims the benefit of Korean Patent Application No. 10-2010-0065423 filed with the Korea Intellectual Property Office on Jul. 7, 2010, the disclosure of which is incorporated herein by reference.

### BACKGROUND OF THE INVENTION

1. Field of the Invention

The present invention relates to a semiconductor device and a method for manufacturing the same; and, more particularly, to a nitride-based semiconductor device for reducing reverse leakage currents and a method for manufacturing the same.

2. Description of the Related Art

In general, a III-nitride-based semiconductor comprised of nitrogen (N) and a III-element (e.g., Ga, Al, In, and so on) is characterized by a wide energy band gap, a high electron mobility and saturation electron speed, and a high heat-chemical stability. A Nitride-based Field Effect Transistor (N-FET) including the III-nitride-based semiconductor is manufactured using a semiconductor material with a wide energy band gap (e.g., GaN, AlGaN, InGaN, and AlINGaN). A typical N-FET is provided with a base substrate, an epi-growth film formed on the base substrate, and a Schottky electrode and an ohmic electrode disposed on the epi-growth film. The nitride-based semiconductor device has a 2-Dimensinal Electron Gas (2DEG) which is generated within the epi-growth film and is used as a current path. The 2DEG may enable the nitride-based semiconductor device to perform forward and reverse operations by being used as a path for transferring ions.

Of nitride-based semiconductor devices, a device with a Schottky diode structure is driven using a Schottky junction formed between a metal and a semiconductor. The nitride-based semiconductor device can perform a switching operation at a high speed and can be driven at a low forward voltage. A typical nitride-based semiconductor device like a Schottky diode has a Schottky electrode forming a Schottky contact with an anode electrode, and an ohmic electrode forming an ohmic contact with a cathode electrode.

However, the Schottky diode with the above-described structure has a problem in that leakage currents flow from the Schottky electrode to the base substrate at the time of a reverse operation. In order to prevent the leakage currents, as the base substrate of the typical nitride-based semiconductor device, there may be used substrates with a resistance value of about more than 1 k ohm, including a Schottky electrode, a silicon carbide substrate, a spinel substrate, and a sapphire substrate. However, even if substrates with the high resistance value are used, it is impossible to prevent any leakage currents. Also, the substrates with high resistance values are relatively expensive. In particular, a widely used silicon wafer with a high resistance value of more than 1 k ohm is even more expensive than other substrates, and thus the price of the silicon wafer causes an increase in costs taken for manufacturing nitride-based semiconductor devices.

### SUMMARY OF THE INVENTION

The present invention has been proposed in order to overcome the above-described problems and it is, therefore, an object of the present invention to provide a nitride-based semiconductor device for preventing reverse leakage currents.

Further, another object of the present invention is to provide a nitride-based semiconductor device for reducing manufacture costs.

Further, another object of the present invention is to provide a method for manufacturing a nitride-based semiconductor device for preventing reverse leakage currents.

Further, another object of the present invention is to provide a method for manufacturing a nitride-based semiconductor device for reducing manufacturing costs.

In accordance with one aspect of the present invention to achieve the object, there is provided a nitride-based semiconductor device including: a base substrate having a diode structure; an epi-growth film disposed on the base substrate; and an electrode part disposed on the epi-growth film, wherein the diode structure includes: first-type semiconductor layers; and a second-type semiconductor layer which is disposed within the first-type semiconductor layers and has both sides covered by the first-type semiconductor layers.

Also, the first-type semiconductor layers are n-type semiconductor layers, and the second-type semiconductor layer is a p-type semiconductor layer.

Also, the base substrate includes: a first-type semiconductor substrate; a second-type impurity doping layer disposed on the semiconductor substrate; and a first-type impurity doping layer disposed on the second-type impurity doping layer.

Also, the semiconductor substrate includes a silicon substrate with a resistance value of less than 1 k ohm, and the base substrate has a resistance value of more than 1 k ohm.

Also, the diode structure is used as a diode for blocking current flowing from the electrode part to the base substrate at the time of a reverse operation of the nitride-based semiconductor device.

Also, the base substrate further includes a buffer layer interposed between the base substrate and the epi-growth film, the buffer layer including a super-lattice layer.

Also, the super-lattice layer is made by alternately forming insulating layers and semiconductor layers.

Also, the epi-growth film includes: a first nitride film on the base substrate; and a second nitride film which is disposed on the first nitride film and has a wider energy band gap than that of the first nitride film, wherein a 2-Dimensional Electron Gas (2DEG) is generated on a boundary between the first nitride film and the second nitride film.

Also, the electrode part includes: a Schottky electrode disposed on the epi-growth layer; an ohmic electrode spaced apart from the Schottky electrode; a gate electrode disposed on the epi-growth layer; a source electrode disposed on one side of the gate electrode; and a drain electrode disposed on the other side of the gate electrode.

Also, the electrode part further includes an ohmic electrode which covers a lower surface of the base substrate.

In accordance with other aspect of the present invention to achieve the object, there is provided a nitride-based semiconductor device including: a base substrate having a diode structure; an epi-growth film disposed on the base substrate; and a Schottky barrier diode structure and a transistor structure disposed on the epi-growth film, wherein the diode structure includes: first-type semiconductor layers; and a second-type semiconductor layer interposed between the first-type semiconductor layers.

Also, the Schottky barrier diode structure includes: a Schottky electrode; and an ohmic electrode spaced apart from the Schottky electrode.

Also, the transistor structure includes: a gate electrode; and a source electrode disposed on one side of the gate electrode; and a drain electrode disposed on the other side of the gate electrode.

Also, the transistor structure includes at least one of a High Electron Mobility Transistor (HEMT), and a Field Effect Transistor (FET).

Also, the epi-growth film includes: a first nitride film on the base substrate; and a second nitride film which is disposed on the first nitride film and has a wider energy band gap than that of the first nitride film, wherein a 2DEG used as a current path of the Schottky barrier diode and the transistor is generated on a boundary of the first nitride film and the second nitride film.

Also, the first-type semiconductor layers are n-type semiconductor layers, and the second-type semiconductor layer is a p-type semiconductor layer.

Also, wherein the base substrate includes: a first-type semiconductor substrate; a second-type impurity doping layer on an upper part of the semiconductor substrate; and a first-type impurity doping layer on an upper part of the second-type impurity doping layer.

Also, the semiconductor substrate includes a silicon substrate with a resistance value of less than 1 k ohm, and the base substrate has a resistance value of more than 1 k ohm.

Also, the diode structure is a diode used for blocking current flowing from the electrode part to the base substrate at the time of a reverse operation of the nitride-based semiconductor device.

In accordance with other aspect of the present invention to achieve the object, there is provided a method for manufacturing a nitride-based semiconductor device including the steps of: preparing a base substrate; forming an epi-growth film on the base substrate by using the base substrate as a seed layer; and forming an electrode part on the epi-growth film, wherein the step of preparing the base substrate comprises a step of forming a diode structure which has first-type semiconductor layers and a second-type semiconductor layer formed within the first-type semiconductor layers.

Also, the step of forming the diode structure includes the steps of: preparing the first-type semiconductor substrate; doping the second-type semiconductor layer on an upper part of the semiconductor substrate; and doping the first-type semiconductor layers on an upper part of the second-type semiconductor layer.

Also, the step of forming the diode structure includes the steps of: preparing the first-type semiconductor substrate; and implanting a second-type impurity ion into the semiconductor substrate.

Also, the step of forming the diode structure includes a step of forming an NPN junction structure.

Also, the step of preparing the base substrate includes the steps of: preparing a silicon substrate with a resistance value of less than 1 k ohm; and forming an NPN junction structure with a resistance value of more than 1 k ohm.

Also, the diode structure is used as a diode for blocking currents flowing from the electrode part to the base substrate at the time of a reverse operation of the nitride-based semiconductor device.

Also, the step of forming the epi-growth film includes the steps of: growing a first nitride film on the base substrate by using the base substrate as a seed layer; and growing a second nitride film, having a wider energy band gap than that of the first nitride film, on the first nitride film by using the first nitride film as a seed layer, wherein a 2DEG is generated on a boundary of the first nitride film and the second nitride film.

Also, the step of forming the electrode part includes the steps of: forming a Schottky electrode on a center of an upper part of the epi-growth film; forming first ohmic electrodes to be spaced apart from the Schottky electrode on an edge of the upper part of the epi-growth film; and forming a second ohmic electrode which covers a lower surface of the base substrate.

In accordance with other aspect of the present invention to achieve the object, there is provided a method for manufacturing a nitride-based semiconductor device includes the steps of: preparing a base substrate; forming an epi-growth film on the base substrate by using the base substrate as a seed layer; forming a Schottky barrier diode structure on the epi-growth film; and forming a transistor structure on the epi-growth film, wherein the step of preparing the base substrate includes the steps of: preparing first-type semiconductor layers; and forming a second-type semiconductor layer formed within the first-type semiconductor layers.

Also, the step of forming the Schottky barrier diode structure includes the steps of: forming a Schottky electrode on the epi-growth film; and forming an ohmic electrode to be spaced apart from the Schottky electrode on the epi-growth film.

Also, the step of forming the transistor structure includes the steps of: forming a gate electrode on the epi-growth film; forming a source electrode at one side of the gate electrode on the epi-growth film; and forming a drain electrode at the other side of the gate electrode on the epi-growth film.

Also, the step of forming the transistor structure includes a step of forming at least one of a High Electron Mobility Transistor (HEMT) and a Field Effect Transistor (FET) on the epi-growth film.

Also, the step of forming the epi-growth film includes the steps of: forming a first nitride film on the base substrate; and forming a second nitride film, having a wider energy band gap than that of the first nitride film, on the first nitride film, wherein a 2DEG used for a current path of the transistor structure and the Schottky barrier diode structure is generated on a boundary of the first nitride film and the second nitride film.

Also, the first-type semiconductor layers are formed with n-type semiconductor layers and the second-type semiconductor layer is formed with a p-type semiconductor layer.

Also, the step of preparing the base substrate includes the steps of: preparing a first-type semiconductor substrate; forming a second-type impurity doping layer on an upper part of the semiconductor substrate; and forming a first-type impurity doping layer on an upper part of the second-type impurity doping layer.

Also, the step of preparing the first-type semiconductor substrate includes a step of preparing a silicon substrate with a resistance value of less than 1 k ohm, and the step of preparing the base substrate includes a step of forming the diode structure with a resistance value of more than 1 k ohm by using the silicon substrate.

Also, the diode structure is used as a diode which blocks currents flowing from the electrode part to the base substrate at the time of a reverse operation of the nitride-based semiconductor device.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a circuit diagram showing a nitride-based semiconductor device in accordance with an embodiment of the present invention;

FIG. 2 is a side view showing a nitride-based semiconductor device in accordance with an embodiment of the present invention;

FIG. 3 is a flowchart showing a method for manufacturing a nitride-based semiconductor device in accordance with an embodiment of the present invention; and

FIGS. 4 to 6 are views showing a process of manufacturing a nitride-based semiconductor device in accordance with an embodiment of the present invention, respectively.

### DETAILED DESCRIPTION OF THE PREFERABLE EMBODIMENTS

The invention now will be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Hereinafter, a nitride-based semiconductor device and a method for manufacturing the same according to the present invention will be described in more detail with reference to the accompanying drawings.

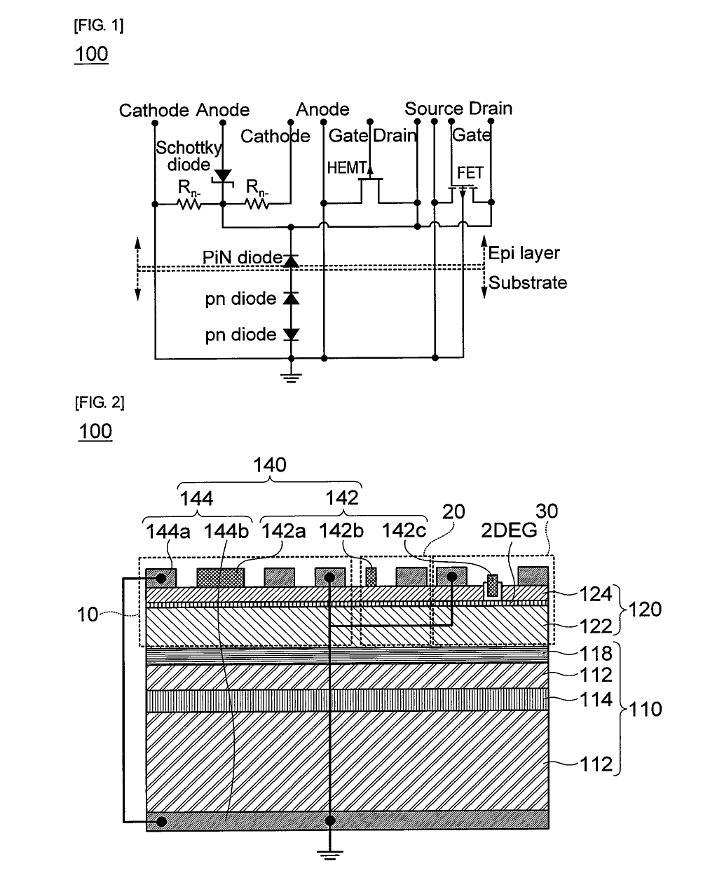

FIG. 1 is a circuit diagram showing a nitride-based semiconductor device in accordance with the embodiment of the present invention. FIG. 2 is a side view showing a nitride-based semiconductor device in accordance with the embodiment of the present invention.

Referring to FIGS. 1 and 2, the nitride-based semiconductor device 100 of the present invention may be a power device which has a Schottky Barrier Diode (SBD) 10 and a transistor structure. The transistor structure may include at least one of a High Electron Mobility Transistor (HEMT) 20 and a Field Effect Transistor (FET) 30.

The nitride-based semiconductor device 100 may include a base substrate 110, an epi-growth film 120, and an electrode part 140.

The base substrate 110 may have a diode structure. For example, the base substrate 110 may include first-type semiconductor layers 112, and a second-type semiconductor layer 114 interposed between the first-type semiconductor layers 112. Thus, the second-type semiconductor layer 114 may be structured to be covered by the first-type semiconductor layers 112. For one example, in case where the first type is an N-type and the second type is a p-type, the diode structure may form an NPN junction diode. For another example, in case where the first type is a p-type and the second type is an n-type, the diode structure may form a PNP junction diode.

The NPN junction diode is manufactured by implanting a p-type semiconductor impurity ion to an upper part of the first-type semiconductor layers (hereinafter, referred to as “n-type semiconductor layers 112”) to thereby form the second-type semiconductor layer (hereinafter, referred to as “p-type semiconductor layer 114”) on the n-type semiconductor layer 112, and then by implanting the first-type impurity ion to an upper part of the p-type semiconductor layer 114 to thereby form the n-type semiconductor layers 112 on the p-type semiconductor layer 114. Also, the NPN junction diode may be formed by implanting a p-type impurity ion into the n-type semiconductor layers 112 at a predetermined depth in such a manner that the p-type semiconductor layer 114 is positioned within the n-type semiconductor layers 112. Herein, the base substrate 110 may be a substrate manufactured by using a silicon substrate with a relatively low resistance value (1 k ohm or less) as a base. A detailed description will be given of a process of manufacturing the base substrate 110.

Meanwhile, a buffer layer 118 may be further formed on the base substrate 110. The buffer layer 118 may have a super-lattice layer structure. The super-lattice layer may have a structure where thin films of different materials are alternately stacked. For one example, the buffer layer 118 may have a multi-layered structure where insulator layers and semiconductor layers are alternately grown. The buffer layer 118 may reduce occurrence of defects resulting from lattice discordance between the base substrate 110 and the epi-growth film 120.

The epi-growth film 120 may be disposed on the base substrate 110. For one example, the epi-growth film 120 may include a first nitride film 122 and a second nitride film 124 which are sequentially stacked on the base substrate 110. The second nitride film 124 may be made of a material with a wider energy band gap than that of the first nitride film 122. In addition, the second nitride film 124 may be made of a material with a lattice factor different from that of the first nitride film 122. For example, the first nitride film 122 and the second nitride film 124 may be films including III-nitride-based materials. In more particular, the first nitride film 122 may be formed of any one, and the second nitride film 124 may be formed of the other one, among from GaN, AlGaN, InGaN, and InAlGaN. For one example, the first nitride film 122 may be a GaN film, and the second nitride film 124 may be an AlGaN film.

In the epi-growth film 120 with the above-mentioned structure, a 2-Dimensional Electron Gas (2DEG) may be generated on a boundary between the first nitride film 122 and the second nitride film 124. During operation of the nitride-based semiconductor device 100, currents may flow through the 2DEG. Herein, currents of the transistor structures 20 and 30 and the Schottky barrier diode 10 may flow through the 2DEG. To this end, the Schottky barrier diode 10 may share the 2DEG with the transistor structures 20 and 30.

The electrode part 140 may include a Schottky electrode 142 and an ohmic electrode 144. The Schottky electrode 142 may include first to third Schottky electrodes 142a to 142c, and the ohmic electrode 144 may include first and second ohmic electrode 144a and 144b. The first to third Schottky electrodes 142a to 142c may be disposed to be spaced apart from one another on an upper part of the epi-growth film 120. The first ohmic electrodes 144a may be disposed on both sides of each of the first to third Schottky electrodes 142a to 142c, respectively. The second ohmic electrode 144b may cover a lower surface of the base substrate 110.

The first Schottky electrode 142a and the first ohmic electrodes 144a disposed on both sides of the first Schottky electrode 142a may form the Schottky barrier diode 10. The first Schottky electrode 142a may be used as an anode of the Schottky barrier diode 10, and the first ohmic electrodes 144a may be used as cathodes of the Schottky barrier diode 10. The second Schottky electrode 142b and the first ohmic electrodes 144a disposed on both sides of the second Schottky electrode 142b may form a High Electron Mobility Transistor (HEMT) 20. The second Schottky electrode 142b may be used as a gate electrode of the HEMT 20, and the first ohmic electrodes 144a disposed on both sides of the second Schottky electrode 142b may be used as each of a drain electrode and a source electrode. The third Schottky electrode 142c and the first ohmic electrodes 144a disposed on both sides of the third Schottky electrode 142c may form a Field Effect Transistor (FET) 30. The third Schottky electrode 142c may be used as a gate electrode of the FET 30, and the first ohmic electrodes 144a disposed on both sides of the third Schottky electrode 142c may be used as each of a source electrode and a drain electrode of the FET 30.

Also, the second ohmic electrode 134b may cover a lower surface of the base substrate 110 at a uniform thickness. The second ohmic electrode 134b and the n-type semiconductor layer 112 of the base substrate 110 may be in ohmic contact with each other. The second ohmic electrode 134b may be electrically connected to the first ohmic electrodes 144a. Thus, during a forward/reverse operation, the first ohmic electrodes 144a and 144b may be configured to be applied voltages at the same time. As described above, the nitride-based semiconductor device 100 of the present invention may include a base substrate 110 with a diode structure, an epi-growth film 120 with the 2DEG, and an electrode part 140. The diode structure may be an NPN junction diode or a PNP junction diode. Thus, the diode structure may be used as a diode for blocking currents flowing from the Schottky electrode 142 to the base substrate 110, when reverse voltages are applied between the ohmic electrode 144 and the Schottky electrode 142 of the electrode part 140. Thus, when the nitride-based semiconductor device 100 is turned off, it is possible to prevent reverse leakage currents, and thus to increase reverse breakdown voltages of the elements and increase mass-production efficiency of the nitride-based semiconductor device 100.

Also, the nitride-based semiconductor device 100 may include a base substrate 110 with a diode structure, an epi-growth film 120 with a 2DEG, and an electrode part 140. In this case, the base substrate 110 may be constructed to have a high resistance of more than 1 k ohm by using a low-priced silicon substrate of less than 1 k ohm as a base. Thus, the nitride-based semiconductor device 100 is constructed with the base substrate 110 with the diode structure for blocking reverse leakage currents, so that it is possible to prevent any reverse leakage currents, as well as to reduce costs taken for manufacturing the elements in comparison with elements using a substrate with a relatively high resistance value.

Hereinafter, a detailed description will be given of a method for manufacturing the nitride-based semiconductor device in accordance with an embodiment of the present invention. Herein, the repeated description thereof will be omitted or simplified. Herein, the following description is associated with a method for manufacturing the nitride-based semiconductor device with an NPN junction structure, except for a method for manufacturing the nitride-based semiconductor device with the base substrate of the PNP junction structure.

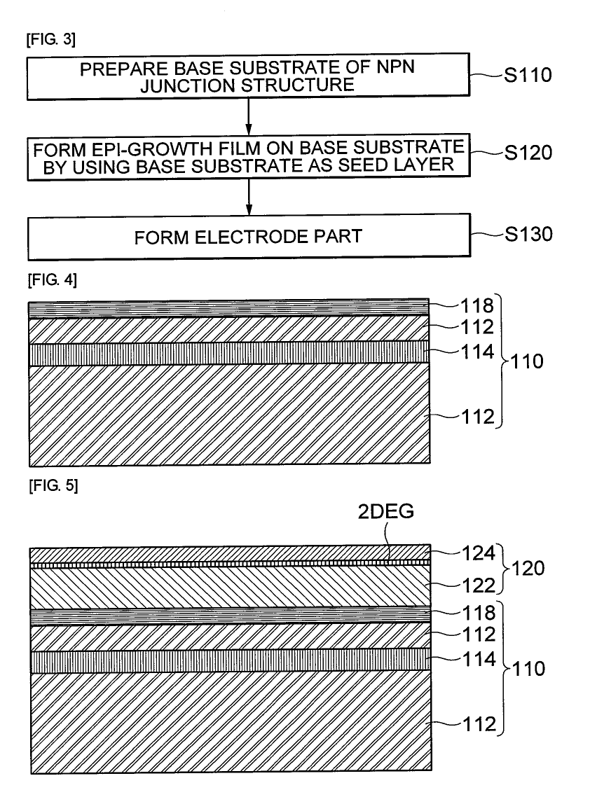

FIG. 3 is a flowchart showing a method for manufacturing the nitride-based semiconductor device in accordance with the embodiment of the present invention. FIGS. 4 to 6 are views showing a process of manufacturing the nitride-based semiconductor device in accordance with the embodiment of the present invention, respectively.

Referring to FIGS. 3 and 4, the base substrate 110 with the NPN junction structure may be prepared (step S110). For one example, the step of preparing the base substrate 110 may include a step of preparing the n-type semiconductor layer 112, a step of forming the p-type semiconductor layer 114 on an upper part of the n-type semiconductor layer 112 by implanting a p-type impurity ion on the n-type semiconductor layer 112, and a step of forming the n-type semiconductor layer 112 into an upper part of the p-type semiconductor layer 114 by implanting the n-type impurity ion into the p-type semiconductor layer 114.

For another example, the step of preparing the base substrate 110 may include a step of preparing the n-type semiconductor layer 112, and a step of forming the p-type semiconductor layer 114 within the n-type semiconductor layer 112 at a predetermined depth by implanting the p-type impurity ion within the n-type semiconductor layer 112.

For the other example, the step of preparing the base substrate 110 may include a step of preparing the n-type semiconductor layer 112, a step of forming the p-type semiconductor layer 114 on the n-type semiconductor layer 112 by using the n-type semiconductor layer 112 as a seed layer, and a step of forming the n-type semiconductor layer 112 on the p-type semiconductor layer 114 by using the p-type semiconductor layer 114 as a seed layer.

Meanwhile, a substrate with a low resistance value may be used as the n-type semiconductor layer 112 of being a base used to manufacture the base substrate 110. In more particular, the base substrate 110 may be a substrate manufactured by using an n-type silicon substrate with a low resistance value of relatively less than 1 k ohm, instead of substrates with high resistance values. In order to prevent reverse leakage currents, the base substrate 110 may generally use at least one of a silicon substrate, a silicon carbide substrate, a spinel substrate, and a sapphire substrate, all of which have high resistance values of about more than 1 k ohm. However, since the substrates described above, in particular, a silicon substrate with a high resistance value of more than 1 k ohm, are relatively expensive, the substrate's price may cause an increase in manufacture costs of the nitride-based semiconductor device 100. Thus, in the nitride-based semiconductor device 100 of the present invention, the base substrate 110 is manufactured by using the n-type silicon substrate with a resistance value of relatively less than 1 k ohm as a base, and implanting a p-type impurity ion into the n-type silicon substrate. Therefore, it is possible to reduce manufacture's costs of the nitride-based semiconductor device 100. In this case, the resistance value of the manufactured base substrate 110 may be more than 1 k ohm. In particular, the base substrate 110 may have an NPN-type diode structure, so that the base substrate 110 may have a significantly high resistance value in terms of characteristics of the NPN-type diode.

Meanwhile, the step of preparing the base substrate 110 may further include a step of forming the buffer layer 118 which covers the n-type semiconductor layer 112 of being an uppermost layer. The step of forming the buffer layer 118 may include a step of forming the super-lattice layer on the n-type semiconductor layer 112. The step of forming the super-lattice layer may be made by alternately forming the insulator layers and the semiconductor layers on the p-type semiconductor layer 114 in a repeated way.

Referring to FIGS. 3 and 5, the epi-growth film 120 may be formed on the base substrate 110 by using the base substrate 110 as a seed layer (step S120). The step of forming the epi-growth film 120 may include a step of forming the first nitride film 122 on the base substrate 110, and a step of forming the second nitride film 124 on the first nitride film 122. For one example, a step of forming the epi-growth film 120 may be made by epitaxial growing the second nitride film 124 by using the first nitride film 122 as a seed layer, followed by epitaxial growing the first nitride film 122 by using the base substrate 110 as a seed layer. The epitaxial growth process for formation of the first and second nitride films 122 and 124 may include at least one of a molecular beam epitaxial growth process, an atomic layer epitaxial growth process, a flow modulation organometallic vapor phase epitaxial growth process, a flow modulation organometallic vapor phase epitaxial growth process, and a hybrid vapor phase epitaxial growth process. Also, as for other example of the process of formation of the first and second nitride films 122 and 124, at least one of a chemical vapor deposition process and a physical vapor deposition process may be used.

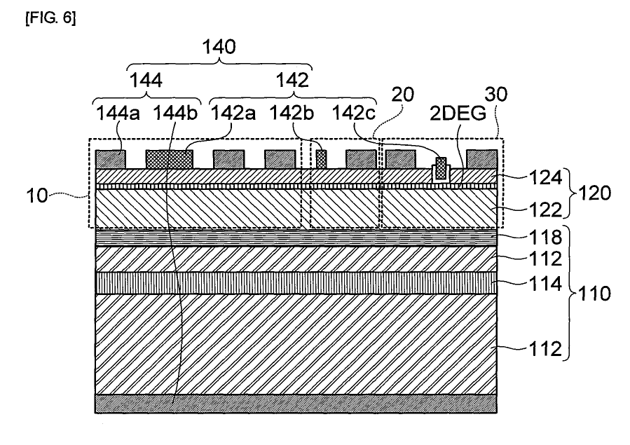

Referring to FIGS. 3 and 6, the electrode part 140 may be formed (step S130). The step of forming the electrode part 140 may include a step of forming the first to third Schottky electrodes 142a to 142c which are spaced apart from one another on an upper part of the epi-growth film 120, and a step of forming the first ohmic electrodes 144a disposed on both sides of each of the first to third Schottky electrodes 142a to 142c on an upper part of the epi-growth film 120. In addition to this, the step of forming the electrode part 140 may further include a step of forming the second ohmic electrode 144b which covers a lower surface of the base substrate 110.

The step of forming the electrode part 140 may include a step of forming a conductive film which covers a lower surface of the base substrate 110 and an upper surface of the epi-growth film 120, and a step of selectively patterning the conductive film which covers the upper surface of the epi-growth film 120. The step of forming the conductive film may be made by forming a metallic film for the lower part of the base substrate 110 and the upper part of the epi-growth film 120, the metallic film including at least one of Al, Mo, Au, Ni, Pt, Ti, Pd, Ir, Rh, Co, W, Ta, Cu, and Zn.

The metallic film formed on one side of the upper part of the epi-growth film 120 is in Schottky contact with the second nitride film 124 of the epi-growth film 120 to thereby be used as the first to third Schottky electrodes 142a to 142c. The metallic film formed on both sides of the first Schottky electrode 142a is in ohmic contact with the second nitride film 124 to thereby be used as the first ohmic electrodes 144a. The first Schottky electrode 142a and the first ohmic electrodes 144a formed on both sides of the first Schottky electrode 142a may form a Schottky barrier diode 10. The second Schottky electrode 142b and the first ohmic electrodes 144a formed on both sides of the second Schottky electrode 142b may form the HEMT 20. And, the third Schottky electrode 142c and the first ohmic electrodes 144a formed on both sides of the third Schottky electrode 142c may form the FET 30. The first ohmic electrodes 144a and the second ohmic electrode 144b are electrically interconnected to each other to thereby be applied voltages at the same time during a forward/reverse operation of the nitride-based semiconductor device 100.

As described above, in the method for manufacturing the nitride-based semiconductor device, the base substrate 110 with the diode structure is prepared, the epi-growth film 120 is grown on the upper part of the base substrate 110, and the electrode part 140 is formed on the epi-growth film 120. At this time, the diode structure may be used as a diode for blocking current flowing from the Schottky electrode 142 of the electrode part 140 to the base substrate 110 during a reverse operation of the nitride-based semiconductor device. Thus, in the method for manufacturing the nitride-based semiconductor device of the present invention, it is possible to prevent reverse leakage currents, which results in an increase in breakdown voltages, as well as an improvement of mass-production efficiency of a nitride-based semiconductor device.

Also, in the method for manufacturing the nitride-based semiconductor device of the present invention, the base substrate 110 with the diode structure is manufactured, and the epi-growth film 120 is grown on the upper part of the base substrate 110. And then, the electrode part 140 is formed on the epi-growth film 120, and the base substrate 110 is formed by implanting impurity ions into a relatively low-priced silicon substrate with a low resistance value. Therefore, in the method for manufacturing the nitride-based semiconductor device, it is possible to prevent any reverse leakage currents, as well as to reduce manufacture costs, in comparison with relatively high-priced substrates with high resistance values.

The nitride-based semiconductor device according to the present invention may be provided with a base substrate with a diode structure, an epi-growth film with the 2DEG, and an electrode part. The diode structure may be an NPN junction diode or a PNP junction diode, and so that when reverse voltages are applied between the Schottky and ohmic electrodes of the electrode part, it can block currents flowing from the Schottky electrode to the ohmic electrode. Therefore, in the nitride-based semiconductor device according to the present invention, at the time of a power-off, it is possible to prevent occurrence of reverse leakage currents, so that it is possible to increase breakdown voltages of elements, as well as to increase mass-production efficiency of the nitride-based semiconductor.

According to the present invention, the nitride based semiconductor device may include a base substrate with a diode structure, a 2DEG, and an electrode part. At this time, the base substrate may be constructed to have a high resistance value of more than 1 k ohm by using a low-priced silicon substrate of relatively less than 1 k ohm as a base. Thus, the nitride based semiconductor device may be constructed to have a base substrate with a diode structure for blocking reverse leakage currents, by using a low-priced silicon substrate as a base. When compared with a relatively high-priced substrate with a high resistance value, the substrate of the present invention can prevent any reverse leakage currents and reduce costs taken for manufacturing elements.

In the method for manufacturing the nitride based semiconductor device of the present invention, a base substrate with a diode structure is prepared, an epi-growth film is grown on an upper part of the base substrate, and then an electrode part is formed on the epi-growth film. At this time, the diode structure may be used a diode for blocking currents flowing from the Schottky electrode to the electrode part during a reverse operation of the nitride based semiconductor device.

Thus, in the method for manufacturing the nitride based semiconductor device, it is possible to prevent occurrence of reverse leakage currents, which results in an increase in breakdown voltages and an improvement of mass-production efficiency in the nitride based semiconductor device.

In the method for manufacturing the nitride based semiconductor device of the present invention, a base substrate with a diode structure is manufactured, an epi-growth film is grown on an upper part of the base substrate, and then an electrode part is formed on the epi-growth film. At this time, the base substrate may be formed by implanting an impurity ion into a relatively low-priced silicon substrate of a low resistance value. Thus, when compared with a relatively high-priced substrate with a high resistance value, it is possible to prevent any reverse leakage currents and reduce manufacture costs.

As described above, although the preferable embodiments of the present invention have been shown and described, it will be appreciated by those skilled in the art that substitutions, modifications and variations may be made in these embodiments without departing from the principles and spirit of the general inventive concept, the scope of which is defined in the appended claims and their equivalents.

What is claimed is:

1. A nitride-based semiconductor device comprising:
a base substrate having a diode structure;
an epi-growth film disposed on the base substrate; and
an electrode part disposed on the epi-growth film,
wherein the diode structure comprises:
first-type semiconductor layers; and
a second-type semiconductor layer which is disposed within the first-type semiconductor layers and has both sides covered by the first-type semiconductor layers.

2. The device of claim 1, wherein the first-type semiconductor layers are n-type semiconductor layers, and the second-type semiconductor layer is a p-type semiconductor layer.

3. The device of claim 1, wherein the base substrate comprises:
a first-type semiconductor substrate;
a second-type impurity doping layer disposed on the semiconductor substrate; and
a first-type impurity doping layer disposed on the second-type impurity doping layer.

4. The device of claim 3, wherein the semiconductor substrate includes a silicon substrate with a resistance value of less than 1 k ohm, and the base substrate has a resistance value of more than 1 k ohm.

5. The device of claim 1, wherein the diode structure is used as a diode for blocking current flowing from the electrode part to the base substrate at the time of a reverse operation of the nitride-based semiconductor device.

6. The device of claim 1, wherein the base substrate further includes a buffer layer interposed between the base substrate and the epi-growth film, the buffer layer including a super-lattice layer.

7. The device of claim 6, wherein the super-lattice layer is made by alternately forming insulating layers and semiconductor layers.

8. The device of claim 1, wherein the epi-growth film comprises:
a first nitride film on the base substrate; and
a second nitride film which is disposed on the first nitride film and has a wider energy band gap than that of the first nitride film,
wherein a 2-Dimensional Electron Gas (2DEG) is generated on a boundary between the first nitride film and the second nitride film.

9. The device of claim 1, wherein the electrode part comprises:
a Schottky electrode disposed on the epi-growth layer;
an ohmic electrode spaced apart from the Schottky electrode;
a gate electrode disposed on the epi-growth layer;
a source electrode disposed on one side of the gate electrode; and
a drain electrode disposed on the other side of the gate electrode.

10. The device of claim 9, wherein the electrode part further includes an ohmic electrode which covers a lower surface of the base substrate.

11. A nitride-based semiconductor device comprising:
a base substrate having a diode structure;
an epi-growth film disposed on the base substrate; and
a Schottky barrier diode structure and a transistor structure disposed on the epi-growth film,
wherein the diode structure comprises:
first-type semiconductor layers; and
a second-type semiconductor layer interposed between the first-type semiconductor layers.

12. The device of claim 11, wherein the Schottky barrier diode structure comprises:
a Schottky electrode; and
an ohmic electrode spaced apart from the Schottky electrode.

13. The device of claim 11, wherein the transistor structure comprises:
a gate electrode; and
a source electrode disposed on one side of the gate electrode; and
a drain electrode disposed on the other side of the gate electrode.

14. The device of claim 11, wherein the transistor structure includes at least one of a High Electron Mobility Transistor (HEMT), and a Field Effect Transistor (FET).

15. The device of claim 11, wherein the epi-growth film comprises:
a first nitride film on the base substrate; and
a second nitride film which is disposed on the first nitride film and has a wider energy band gap than that of the first nitride film,
wherein a 2DEG used as a current path of the Schottky barrier diode and the transistor is generated on a boundary of the first nitride film and the second nitride film.

16. The device of claim 11, wherein the first-type semiconductor layers are n-type semiconductor layers, and the second-type semiconductor layer is a p-type semiconductor layer.

17. The device of claim 11, wherein the base substrate comprises:
a first-type semiconductor substrate;
a second-type impurity doping layer on an upper part of the semiconductor substrate; and
a first-type impurity doping layer on an upper part of the second-type impurity doping layer.

18. The device of claim 11, wherein the semiconductor substrate includes a silicon substrate with a resistance value of less than 1 k ohm, and the base substrate has a resistance value of more than 1 k ohm.

19. The device of claim 11, wherein the diode structure is a diode used for blocking current flowing from the electrode part to the base substrate at the time of a reverse operation of the nitride-based semiconductor device.

20. A method for manufacturing a nitride-based semiconductor device comprising the steps of:
preparing a base substrate;
forming an epi-growth film on the base substrate by using the base substrate as a seed layer; and
forming an electrode part on the epi-growth film,
wherein the step of preparing the base substrate comprises a step of forming a diode structure which has first-type semiconductor layers and a second-type semiconductor layer formed within the first-type semiconductor layers.

21. The method of claim 20, wherein the step of forming the diode structure comprises the steps of:
preparing the first-type semiconductor substrate;
doping the second-type semiconductor layer on an upper part of the semiconductor substrate; and
doping the first-type semiconductor layers on an upper part of the second-type semiconductor layer.

22. The method of claim 20, wherein the step of forming the diode structure comprises the steps of:
preparing the first-type semiconductor substrate; and
implanting a second-type impurity ion into the semiconductor substrate.

23. The method of claim 20, wherein the step of forming the diode structure comprises a step of forming an NPN junction structure.

24. The method of claim 20, wherein the step of preparing the base substrate comprises the steps of:
preparing a silicon substrate with a resistance value of less than 1 k ohm; and
forming an NPN junction structure with a resistance value of more than 1 k ohm.

25. The method of claim 20, wherein the diode structure is used as a diode for blocking currents flowing from the electrode part to the base substrate at the time of a reverse operation of the nitride-based semiconductor device.

26. The method of claim 20, wherein the step of forming the epi-growth film comprises the steps of:
growing a first nitride film on the base substrate by using the base substrate as a seed layer; and
growing a second nitride film, having a wider energy band gap than that of the first nitride film, on the first nitride film by using the first nitride film as a seed layer,
wherein a 2DEG is generated on a boundary of the first nitride film and the second nitride film.

27. The method of claim 20, wherein the step of forming the electrode part comprises the steps of:
forming a Schottky electrode on a center of an upper part of the epi-growth film;
forming first ohmic electrodes to be spaced apart from the Schottky electrode on an edge of the upper part of the epi-growth film; and
forming a second ohmic electrode which covers a lower surface of the base substrate.

28. A method for manufacturing a nitride-based semiconductor device comprises the steps of:
preparing a base substrate;
forming an epi-growth film on the base substrate by using the base substrate as a seed layer;
forming a Schottky barrier diode structure on the epi-growth film; and
forming a transistor structure on the epi-growth film,
wherein the step of preparing the base substrate comprises the steps of:
preparing first-type semiconductor layers; and
forming a second-type semiconductor layer formed within the first-type semiconductor layers.

29. The method of claim 28, wherein the step of forming the Schottky barrier diode structure comprises the steps of:
forming a Schottky electrode on the epi-growth film; and
forming an ohmic electrode to be spaced apart from the Schottky electrode on the epi-growth film.

30. The method of claim 28, wherein the step of forming the transistor structure comprises the steps of:
forming a gate electrode on the epi-growth film;
forming a source electrode at one side of the gate electrode on the epi-growth film; and
forming a drain electrode at the other side of the gate electrode on the epi-growth film.

31. The method of claim 28, wherein the step of forming the transistor structure comprises a step of forming at least one of a High Electron Mobility Transistor (HEMT) and a Field Effect Transistor (FET) on the epi-growth film.

32. The method of claim 28, wherein the step of forming the epi-growth film comprises the steps of:
forming a first nitride film on the base substrate; and
forming a second nitride film, having a wider energy band gap than that of the first nitride film, on the first nitride film,
wherein a 2DEG used for a current path of the transistor structure and the Schottky barrier diode structure is generated on a boundary of the first nitride film and the second nitride film.

33. The method of claim 28, wherein the first-type semiconductor layers are formed with n-type semiconductor layers and the second-type semiconductor layer is formed with a p-type semiconductor layer.

34. The method of claim 28, wherein the step of preparing the base substrate comprises the steps of:
preparing a first-type semiconductor substrate;
forming a second-type impurity doping layer on an upper part of the semiconductor substrate; and
forming a first-type impurity doping layer on an upper part of the second-type impurity doping layer.

35. The method of claim 28, wherein the step of preparing the first-type semiconductor substrate comprises a step of preparing a silicon substrate with a resistance value of less than 1 k ohm, and the step of preparing the base substrate comprises a step of forming the diode structure with a resistance value of more than 1 k ohm by using the silicon substrate.

36. The method of claim 28, wherein the diode structure is used as a diode which blocks currents flowing from the electrode part to the base substrate at the time of a reverse operation of the nitride-based semiconductor device.
